(19) United States
(12) Patent Application Publication
(10) Pub. No.: US 2025/0006860 A1
(43) Pub. Date: Jan. 2, 2025

(54) DISPLAY ELEMENT AND MANUFACTURING METHOD THEREOF

(71) Applicant: AUO Corporation, Hsin-Chu (TW)

(72) Inventors: Chih-Che KUO, Hsin-Chu (TW); Seok-Lyul LEE, Hsin-Chu (TW); Yu-Chieh LIN, Hsin-Chu (TW)

(21) Appl. No.: 18/394,182

(22) Filed: Dec. 22, 2023

(30) Foreign Application Priority Data
Jun. 27, 2023 (TW) 112123958

(51) Int. Cl. H01L 33/06; H01L 25/075; H01L 25/16; H01L 27/12; H01L 33/62

(52) U.S. Cl. CPC H01L 33/06; H01L 25/0753; H01L 25/167; H01L 27/1255; H01L 33/62; H01L 2933/0016; H01L 2933/0066

(57) ABSTRACT

A display element includes a substrate, a three-colored LED light emitting structure, a first insulation layer, a first active device layer, at least one conductive via and at least one electrode. The three-colored LED light emitting structure is located on the substrate. The first insulation layer is located on the fourth semiconductor layer. The first active device layer is located on the first insulation layer, and the first active device layer includes at least one transistor. The conductive via extends from the first active device layer to and electrically connects at least one of the first semiconductor layer, the second semiconductor layer, the third semiconductor layer and the fourth semiconductor layer. The electrode is located upon the first active device layer.

### RELATED APPLICATIONS

This application claims priority to Taiwan Application Serial Number 112123958, filed Jun. 27, 2023, which is herein incorporated by reference.

### BACKGROUND

### Field of Invention

The present disclosure relates to a display element and a manufacturing method of a display element.

### Description of Related Art

As the rapid progress of electrical technology, display devices have been widely applied in the life of people, such as cellphones and computers. In these products, the unit area of a light-emitting element becomes smaller and smaller as the resolution improves. Generally, a light-emitting element can be divided into two areas, a control circuit area and a light-emitting area. Since the control circuit area doesn't emit light, if the control circuit area is disposed beside the light-emitting area, the effective light-emitting area will decrease, which will cause a difficulty to have both resolution and brightness.

A general solution of the above problem is to separately manufacture the control circuit area and the light-emitting area first, and then stack the control circuit on the light-emitting structure through transferring and bonding to solve the insufficiency of resolution. However, the technology of transferring and bonding needs to consider the bonding strength between two components and the yield of the process. The solution mentioned above is feasible but not complete.

### SUMMARY

One aspect of the present disclosure provides a display element.

According to one embodiment of the present disclosure, a display element includes a substrate, a three-colored LED light emitting structure, a first insulation layer, a first active device layer, at least one conductive via or conductive pillar and at least one electrode. The three-colored LED light emitting structure is located on the substrate. The three-colored LED light emitting structure includes a first semiconductor layer, a first multi-quantum-well layer, a second semiconductor layer, a second multi-quantum-well layer, a third semiconductor layer, a third multi-quantum-well layer and a fourth semiconductor layer. The first semiconductor layer is located on the substrate. The first multi-quantum well layer is located on the first semiconductor layer. The second semiconductor layer is located on the first multi-quantum well layer. The second multi-quantum well layer is located on the second semiconductor layer. The third semiconductor layer is located on the second multi-quantum well layer. The third multi-quantum well layer is located on the third semiconductor layer. The fourth semiconductor layer is located on the third multi-quantum well layer. The first insulation layer is located on the fourth semiconductor layer. The first active device layer is located on the first insulation layer, and the first active device layer includes at least one transistor. The conductive via of the conductive pillar extends from the first active device layer to and electrically connects at least one of the first semiconductor layer, the second semiconductor layer, the third semiconductor layer and the fourth semiconductor layer. The electrode is located upon the first active device layer.

In some embodiments of the present disclosure, the transistor includes a semiconductor active layer, a gate electrode, a source or drain and a drain or source. The gate electrode electrically connects to one of the electrodes and achieves a purpose of current control through an electric field induction to a carrier in the semiconductor active layer across an insulation material. The source or drain electrically connects to one of the electrodes. The drain or source electrically connects to the three-colored LED light emitting structure through the conductive via.

In some embodiments of the present disclosure, the semiconductor active layer includes a same material as the first semiconductor layer, the second semiconductor layer, the third semiconductor layer or the fourth semiconductor layer.

In some embodiments of the present disclosure, the display element further includes a second insulation layer and a fifth semiconductor layer. The second insulation layer is located between the third semiconductor layer and the third multi-quantum well layer. The fifth semiconductor layer is located between the second insulation layer and the third multi-quantum well layer.

In some embodiments of the present disclosure, the display element further includes a third insulation layer and a sixth semiconductor layer. The third insulation layer is located between the second semiconductor layer and the second multi-quantum well layer. The sixth semiconductor layer is located between the third insulation layer and the second multi-quantum well layer.

In some embodiments of the present disclosure, an amount of the transistor is three, an amount of the conductive via is six, and the six conductive vias electrically connects to the first semiconductor layer, the second semiconductor layer, the third semiconductor layer, the fourth semiconductor layer, the fifth semiconductor layer and the sixth semiconductor layer respectively.

In some embodiments of the present disclosure, the first active device layer includes an insulation material configured to electrically isolate the transistors.

In some embodiments of the present disclosure, the display element further includes a second active device layer. The second active device layer is located on the first active device layer and electrically connects to the first active device layer.

In some embodiments of the present disclosure, the second active device layer includes at least one capacitor. The capacitor electrically connects to one of the electrodes.

In some embodiments of the present disclosure, an amount of the transistor is six, an amount of the conductive via is six, an amount of the capacitor is three, three of the six transistors electrically connects to the three-colored LED light emitting structure.

In some embodiments of the present disclosure, the gate electrode of three of the six transistors electrically connects to the three capacitors and the source or the drain of the other three of the six transistors.

Another aspect of the present disclosure provides a manufacturing method of a display element.

According to one embodiment of the present disclosure, a manufacturing method of a display element includes forming a three-colored LED light emitting structure on a substrate, in which the three-colored LED light emitting structure includes a first semiconductor layer, a first multi-quantum well layer, a second semiconductor layer, a second multi-quantum well layer, a third semiconductor layer, a third multi-quantum well layer and a fourth semiconductor layer stacked in order; forming a first insulation layer on the three-colored LED light emitting structure; forming at least one conductive via in the three-colored LED light emitting structure and the first insulation layer, in which the conductive via electrically connects at least one of the first semiconductor layer, the second semiconductor layer, the third semiconductor layer and the fourth semiconductor layer; forming a first active device layer on the first insulation layer, in which the first active device layer includes at least one transistor; and forming at least one electrode upon the first active device layer.

In some embodiments of the present disclosure, forming the conductive via in the three-colored LED light emitting structure and the first insulation layer includes coating a photoresist on the first insulation layer; patterning the photoresist to form at least one opening; etching the three-colored LED light emitting structure and the first insulation layer in the opening to form at least one via hole; filling an insulation liner layer in the via hole; and plating a conductive material on the insulation liner layer to form the conductive via or filling the via hole to form a conductive pillar.

In some embodiments of the present disclosure, the manufacturing method of the display element further includes forming a second insulation layer on the third semiconductor layer; and forming a fifth semiconductor layer on the second insulation layer.

In some embodiments of the present disclosure, the manufacturing method of the display element further includes forming a third insulation layer on the second semiconductor layer; and forming a sixth semiconductor layer on the third insulation layer.

In some embodiments of the present disclosure, the manufacturing method of the display element further includes depositing a semiconductor layer on the first insulation layer, wherein the semiconductor layer has a same material as the first semiconductor layer or the second semiconductor layer; patterning the semiconductor layer to form at least one semiconductor active layer; and forming at least one source and at least one drain on two opposite sides of the semiconductor active layer.

In some embodiments of the present disclosure, forming the semiconductor active layer and the three-colored LED light emitting structure is formed by Metal-Organic Chemical Vapor Deposition (MOCVD).

In the aforementioned embodiments of the present disclosure, since each layer of the three-colored LED light emitting structure is stacked in order on the same substrate in the manufacturing process, and the conductive via and the active device layer that includes control circuit are form on the three-colored LED light emitting structure afterwards, problems such as the effect on the yield and the process time caused by the transferring accuracy in the transferring and bonding process, the bonding strength between two components and the reliability are avoided as a result. Furthermore, the control circuit is located directly on the three-colored LED light emitting structure, which effectively reduces the area of a single element and improves the resolution and the effective light-emitting area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a cross-sectional view of a display element according to one embodiment of the present disclosure.

FIG. 2 is a cross-sectional view of a display element according to another embodiment of the present disclosure.

FIG. 3 is a cross-sectional view of a display element according to yet another embodiment of the present disclosure.

FIG. 4 is a top view of the display element of FIG. 3.

FIG. 5 is a top view of the first active device layer of the display element of FIG. 3.

FIG. 6 is an equivalent circuit diagram of the display element of FIG. 3.

FIG. 7 is a cross-sectional view of a display element according to yet another embodiment of the present disclosure.

FIG. 8 is a top view of the display element of FIG. 7.

FIG. 9 is a top view of the first active device layer of the display element of FIG. 7.

FIG. 10 is a top view of the second active device layer of the display element of FIG. 7.

FIG. 11 is an equivalent circuit diagram of the display element of FIG. 7.

FIG. 12 is a flow chart of the manufacturing method of the display element according to one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As used herein, “about”, “about”, “approximately” or “substantially” generally means within 20 percent, or within 10 percent, or within 20 percent of a given value or range of 5. Numerical quantities given herein are approximations, indicating that the use of terms such as “about,” “approximately,” “approximately,” or “substantially” can be inferred when not explicitly stated.

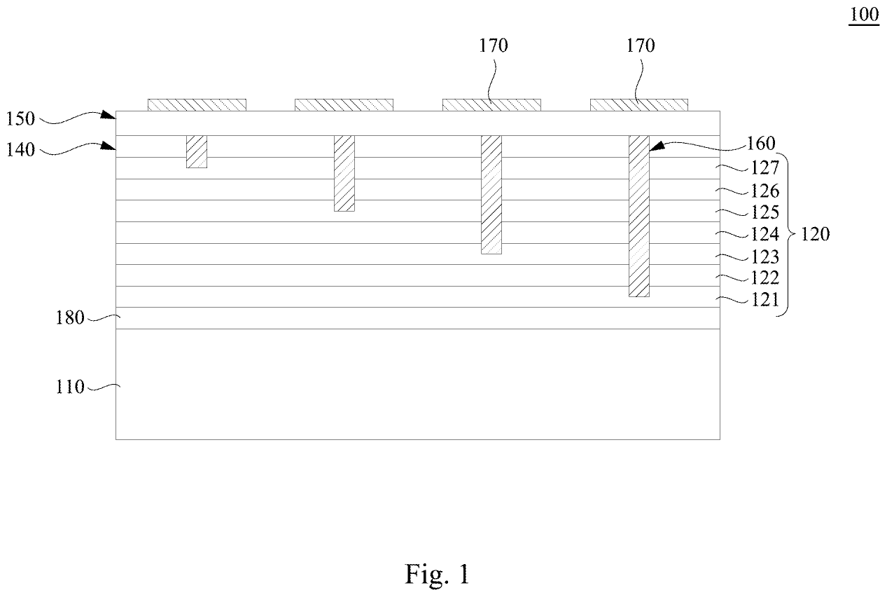

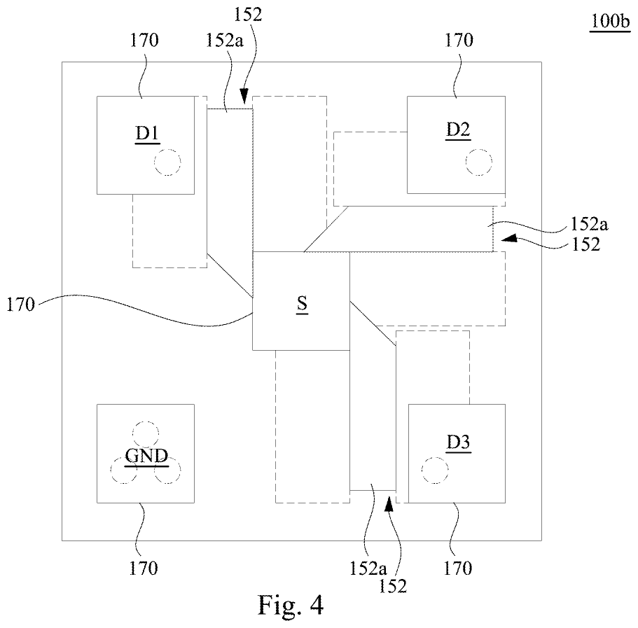

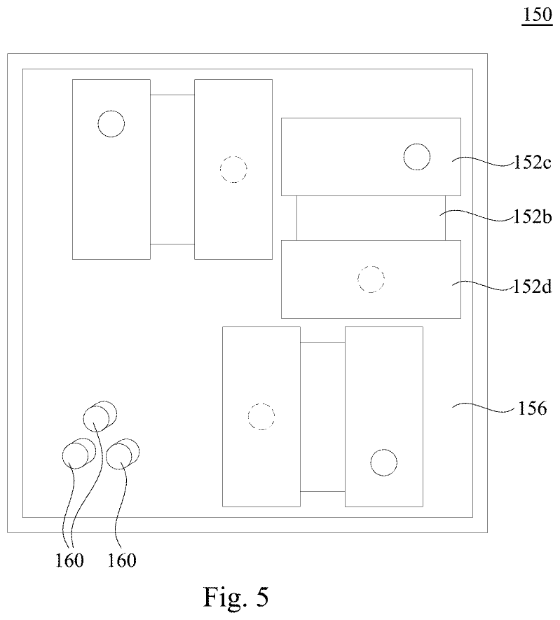

FIG. 1 is a cross-sectional view of a display element 100 according to one embodiment of the present disclosure. Refer to FIG. 1, a display element 100 includes a substrate 110, a three-colored LED light emitting structure 120, a first insulation layer 140, a first active device layer 150, at least one conductive via 160 (or conductive pillar) and at least one electrode 170. Herein, a conductive via is intended to be a metal pillar that fills the conductive via 160 with conductive material. The three-colored LED light emitting structure 120 is located on the substrate 110. The three-colored LED light emitting structure 120 includes a first semiconductor layer 121, a first multi-quantum-well layer 122, a second semiconductor layer 123, a second multi-quantum-well layer 124, a third semiconductor layer 125, a third multi-quantum-well layer 126 and a fourth semiconductor layer 127. The first semiconductor layer 121 is located on the substrate 110. In some embodiments, a buffer layer 180 can be disposed between the first semiconductor layer 121 and the substrate 110. The first multi-quantum well layer 122 is located on the first semiconductor layer 121. The second semiconductor layer 123 is located on the first multi-quantum well layer 122. The second multi-quantum well layer 124 is located on the second semiconductor layer 123. The third semiconductor layer 125 is located on the second multi-quantum well layer 124. The third multi-quantum well layer 126 is located on the third semiconductor layer 125. The fourth semiconductor layer 127 is located on the third multi-quantum well layer 126. The first insulation layer 140 is located on the fourth semiconductor layer 127. The first active device layer 150 is located on the first insulation layer 140, and the first active device layer 150 includes at least one transistor 152, which will be described later in FIG. 4 and FIG. 5. Every of the conductive vias 160 (or conductive pillar) extends from the first active device layer 150 to and electrically connects one of the first semiconductor layer 121, the second semiconductor layer 123, the third semiconductor layer 125 and the fourth semiconductor layer 127. In the present embodiment, the four conductive vias 160 from left to right of FIG. 1 extends from the first active device layer 150 to and electrically connects the fourth semiconductor layer 127, the third semiconductor layer 125, the second semiconductor layer 123 and the first semiconductor layer 121 respectively. Furthermore, the electrode 170 is located on the first active device layer 150.

In the present embodiment, the material of the first semiconductor layer 121 and the third semiconductor layer 125 are semiconductor materials with the same type of dopant, the material of the second semiconductor layer 123 and the fourth semiconductor layer 127 are semiconductor materials with the same other type of dopant, the first semiconductor layer 121 and the second semiconductor layer 123 are semiconductors with carriers that has opposite electricity. As an example, if the material of the first semiconductor layer 121 was an n-type semiconductor material, the material of the second semiconductor layer 123 is a p-type semiconductor material. On the other hand, if the material of the first semiconductor layer 121 was a p-type semiconductor material, the material of the second semiconductor layer 123 is an n-type semiconductor material. In practical applications, the first semiconductor layer 121, the second semiconductor layer 123, the third semiconductor layer 125 and the fourth semiconductor layer 127 can include gallium nitride (GaN), aluminum nitride (AlN), indium nitride (InN), indium gallium nitride (InₓGa₍₁₋ₓ₎N), a combination thereof, or the like.

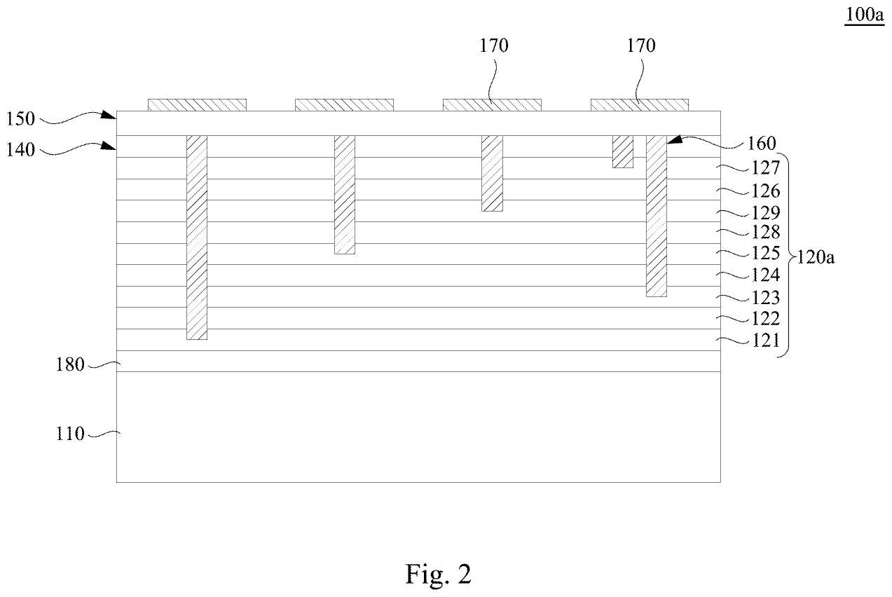

FIG. 2 is a cross-sectional view of a display element 100a according to another embodiment of the present disclosure. Refer to FIG. 2, a display element 100a includes a substrate 110, a three-colored LED light emitting structure 120a, a first insulation layer 140, a first active device layer 150, at least one conductive via 160 (or conductive pillar) and at least one electrode 170. The substrate 110, the first insulation layer 140, the first active device layer 150 and the electrodes 170 has a similar structure as the structure of FIG. 1, so they will not be repeated. In the present embodiment, the three-colored LED light emitting structure 120a of the display element 100a further includes a second insulation layer 128 and a fifth semiconductor layer 129. The second insulation layer 128 is located between the third semiconductor layer 125 and the third multi-quantum well layer 126. The fifth semiconductor layer 129 is located between the second insulation layer 128 and the third multi-quantum well layer 126. In addition, Every of the conductive vias 160 (or conductive pillar) extends from the first active device layer 150 to and electrically connects one of the first semiconductor layer 121, the second semiconductor layer 123, the third semiconductor layer 125, the fourth semiconductor layer 127 and the fifth semiconductor layer 129. For example, the conductive via 160 on the far left of FIG. 2 extends from the first active device layer 150 to the first semiconductor layer 121 and electrically connects the first semiconductor layer 121. In the present embodiment, the material of the first semiconductor layer 121, the third semiconductor layer 125 and the fifth semiconductor layer 129 are semiconductor materials with the same type of dopant, the material of the second semiconductor layer 123 and the fourth semiconductor layer 127 are semiconductor materials with the same other type of dopant, the first semiconductor layer 121 and the second semiconductor layer 123 are semiconductors with carriers that has opposite electricity.

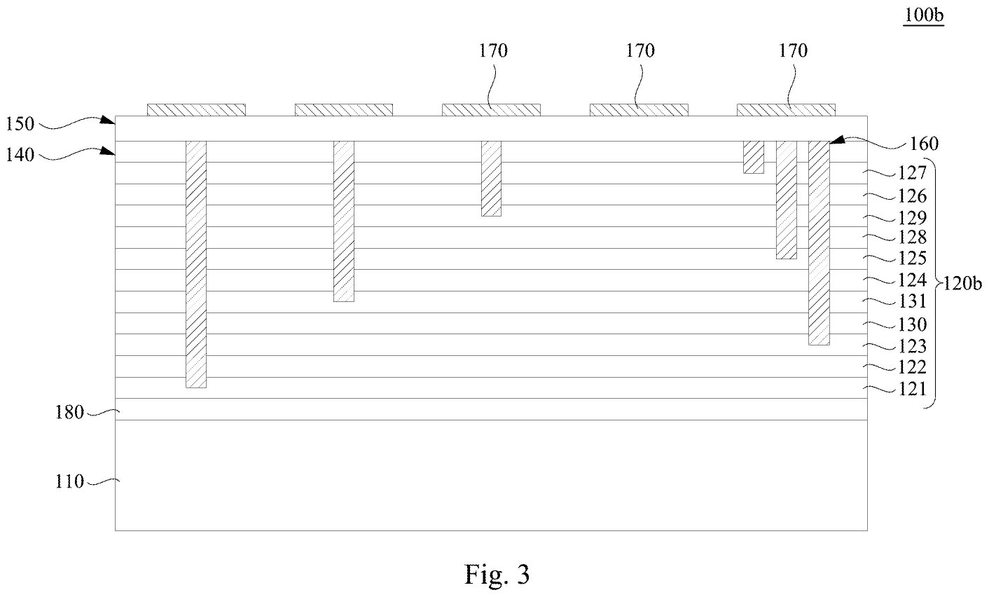

FIG. 3 is a cross-sectional view of a display element 100b according to yet another embodiment of the present disclosure. Refer to FIG. 3, a display element 100b includes a substrate 110, a three-colored LED light emitting structure 120b, a first insulation layer 140, a first active device layer 150, at least one conductive via 160 (or conductive pillar) and at least one electrode 170. The substrate 110, the first insulation layer 140, the first active device layer 150 and the electrodes 170 has a similar structure as the structure of FIG. 1, so they will not be repeated. In the present embodiment, the three-colored LED light emitting structure 120b of the display element 100b further includes a third insulation layer 130 and a sixth semiconductor layer 131. The third insulation layer 130 is located between the second semiconductor layer 123 and the second multi-quantum well layer 124. The sixth semiconductor layer 131 is located between the third insulation layer 130 and the second multi-quantum well layer 124.

FIG. 4 is a top view of the display element 100b of FIG. 3. FIG. 5 is a top view of the first active device layer 150 of the display element 100b of FIG. 3. Refer to FIG. 3 to FIG. 5, the first active device layer 150 includes at least one transistor 152. The transistor 152 includes a semiconductor active layer 152b, a gate electrode 152a, a source 152c and a drain 152d. The gate electrode 152a electrically connects to one of the electrodes 170 (the electrode 170 located at the center of FIG. 4) and achieves a purpose of current control through an electric field induction to a carrier in the semiconductor active layer 152b across an insulation material 156. The source electrically connects to one of the electrodes 170 (the electrode 170 located at the corner of FIG. 4). The drain 152d electrically connects to the three-colored LED light emitting structure 120b through the conductive via 160. In the present embodiment, an amount of the transistor 152 is three, an amount of the conductive via 160 is six, and the six conductive vias 160 electrically connects to the first semiconductor layer 121, the second semiconductor layer 123, the third semiconductor layer 125, the fourth semiconductor layer 127, the fifth semiconductor layer 129 and the sixth semiconductor layer 131 respectively. In the present embodiment, the lower-left electrode 170 (the electrode 170 located at the far right of FIG. 3) electrically connects three conductive vias 160, and the three conductive vias 160 electrically connects to the fourth semiconductor layer 127, the third semiconductor layer 125 and the second semiconductor layer 123 respectively. The three drains 152d of the three transistors 152 electrically connects to the first semiconductor layer 121, the sixth semiconductor layer 131 and the fifth semiconductor layer 129 through a conductive via 160 respectively. The first active device layer 150 includes an insulation material 156 configured to electrically isolate the three transistors 152. The semiconductor active layer 152b includes a same material as the first semiconductor layer 121, the second semiconductor layer 123, the third semiconductor layer 125 or the fourth semiconductor layer 127, such as gallium nitride (GaN), aluminum nitride (AlN), indium nitride (InN), indium gallium nitride (InₓGa₍₁₋ₓ₎N), a combination thereof, or other suitable materials. The material of the sources 152c and the drains 152d of the transistors 152 can include conductive metals, such as gold, but not limited to this. The material of the electrodes 170 and the conductive vias 160 can include conductive metals.

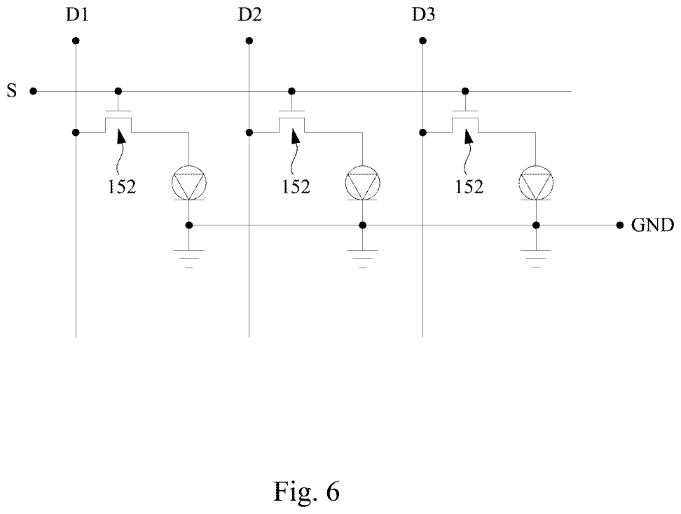

FIG. 6 is an equivalent circuit diagram of the display element of FIG. 3. Refer to FIG. 3, FIG. 4 and FIG. 6, the data line D1, D2, D3, the scan line S and the ground line GND electrically connects the five electrodes 170 respectively (as shown in FIG. 4). The three transistors 152 controls the first multi-quantum well layer 122, the second multi-quantum well layer 124 and the third multi-quantum well layer 126 through conductive vias 160 respectively to emit lights with three colors. In the present embodiment, the first multi-quantum well layer 122 can emit a blue light, the second multi-quantum well layer 124 can emit a green light, and the third multi-quantum well layer 126 can emit a red light, but the disclosure is not limited to this. In other embodiments, the three-colored LED light emitting structure 120b can include additional layers, such as a distributed Bragg reflector (DBR). The embodiments mentioned above can all prevent the three-colored LED light emitting structure 120b from mutual excitations between layers caused by vertical stack, which results in the color mixture beyond control.

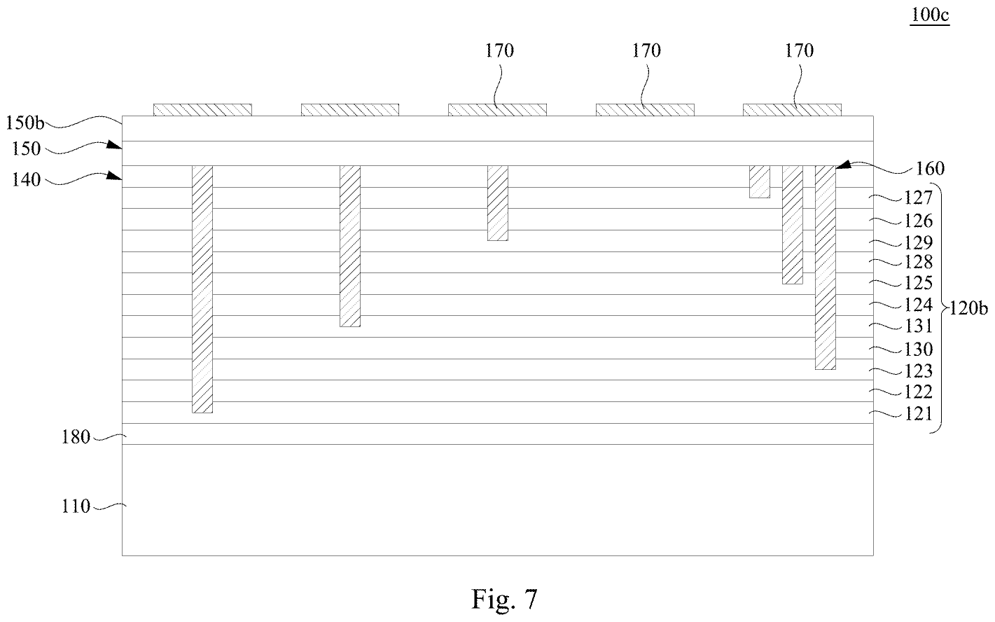

FIG. 7 is a cross-sectional view of a display element 100c according to yet another embodiment of the present disclosure. Refer to FIG. 7, a display element 100c includes a substrate 110, a three-colored LED light emitting structure 120b, a first insulation layer 140, a first active device layer 150, at least one conductive via 160 (or conductive pillar) and at least one electrode 170. The difference between the embodiment of FIG. 7 and the embodiment of FIG. 3 is that, in the present embodiment, the display element 100c further includes a second active device layer 150b. The second active device layer 150b is located on the first active device layer 150, and the second active device layer 150b electrically connects to the first active device layer 150. In the present embodiment, the amount of the transistors 152 included in the first active device layer 150 and the electrical components included in the second active device layer 150b will be different, which will be described in detail below.

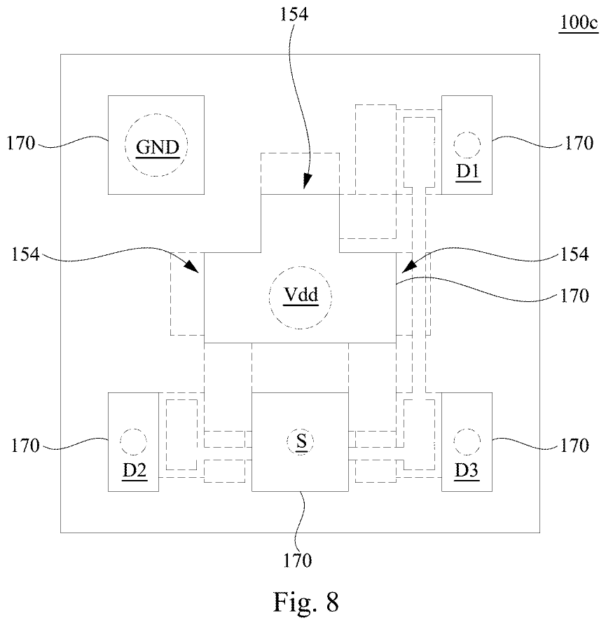

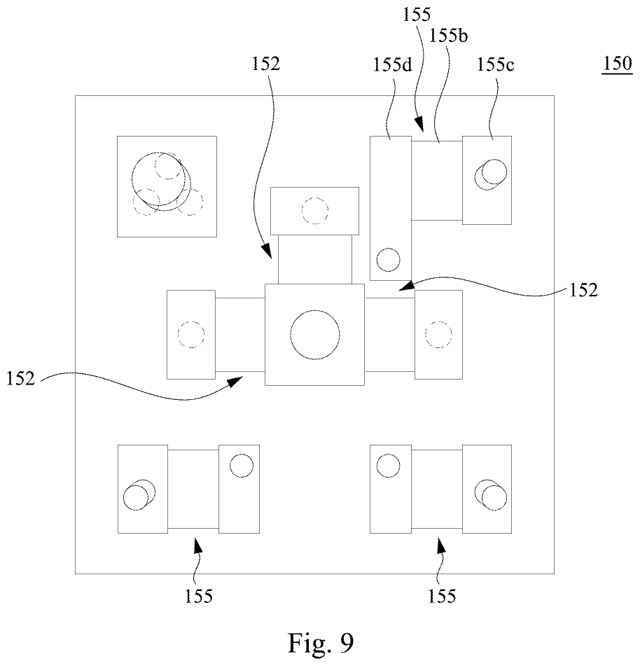

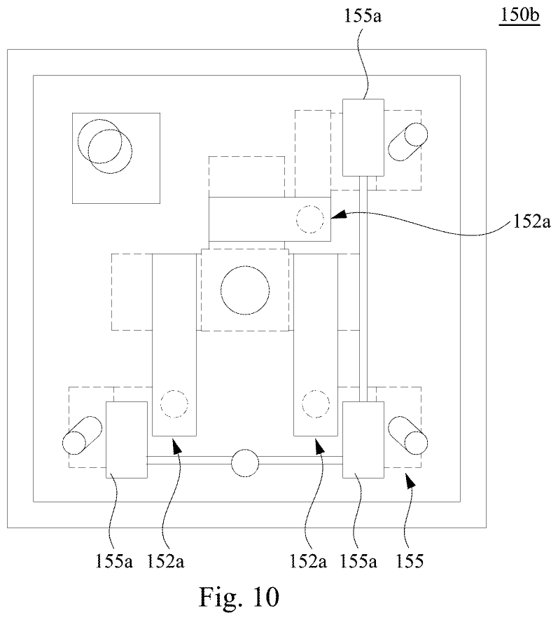

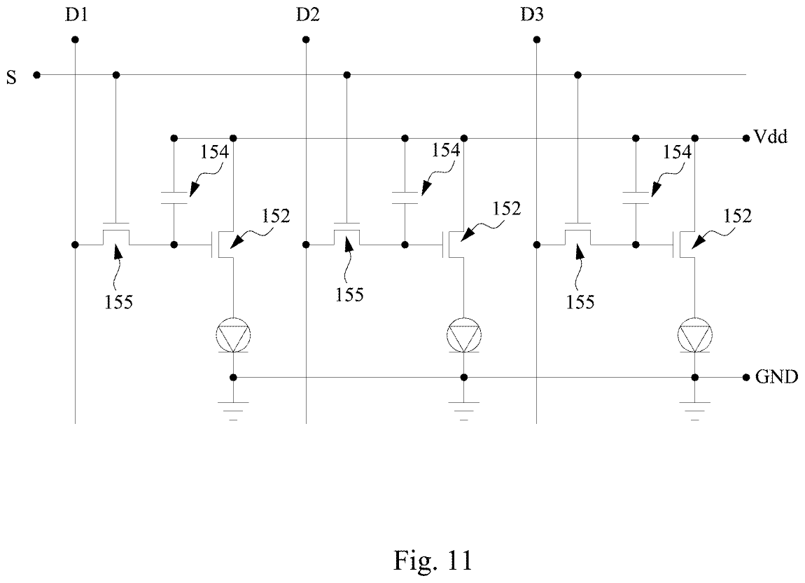

FIG. 8 is a top view of the display element 100c of FIG. 7. FIG. 9 is a top view of the first active device layer 150 of the display element 100c of FIG. 7. FIG. 10 is a top view of the second active device layer 150b of the display element 100c of FIG. 7. Refer to FIG. 7 to FIG. 10, the second active device layer 150b includes at least one capacitor 154. The capacitor 154 electrically connects to one of the electrodes 170. In the present embodiment, the upper electrode plate of the capacitor 154 is the electrode 170 located at the center, the lower electrode plate of the capacitor 154 is the three gate electrodes 152a located at the center of the second active device layer 150b. In the present embodiment, an amount of the transistor 152, 155 is six, an amount of the conductive via 160 is six, an amount of the capacitor 154 is three, three of the six transistors 152 (the three transistors 152 located in the center of FIG. 9 that share a drain, known as drive transistor) electrically connects to the three-colored LED light emitting structure 120b. In addition, using the transistors 155 with a channel that includes a p-type semiconductor as an example, the gate electrode 152a of the three transistors 152 is simultaneously the lower electrode plate of the capacitor 154, and electrically connects to the drain 155d of the other three of the six transistors 155 (the three transistors 155 located in the three corners of FIG. 9, known as switch transistor). However, the disclosure can also use transistors 155 with a channel that includes a n-type semiconductor as the switch transistors, in which the gate electrode 152a of the three transistors 152 electrically connects to the source of the switch transistors 155. FIG. 11 is an equivalent circuit diagram of the display element 100c of FIG. 7, in which each of the LED unit (corresponds to two semiconductor layers and one multi-quantum well layer) is controlled by two transistors 152, 155 (one switch transistor 155 and one drive transistor 152 each) and one capacitor 154. The data line D1, D2, D3, the scan line S, the ground line GND and the bias line Vdd electrically connects the six electrodes 170 respectively (as shown in FIG. 8).

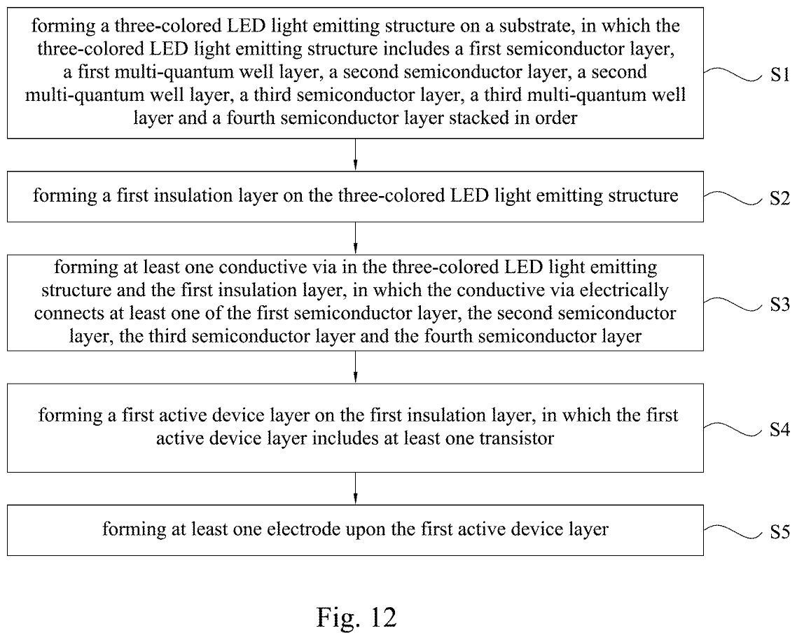

FIG. 12 is a flow chart of the manufacturing method of the display element according to one embodiment of the present disclosure. Refer to FIG. 12, the manufacturing method of the display element includes the following steps: first in step S1, forming a three-colored LED light emitting structure on a substrate, in which the three-colored LED light emitting structure includes a first semiconductor layer, a first multi-quantum well layer, a second semiconductor layer, a second multi-quantum well layer, a third semiconductor layer, a third multi-quantum well layer and a fourth semiconductor layer stacked in order; then in step S2, forming a first insulation layer on the three-colored LED light emitting structure; then in step S3, forming at least one conductive via in the three-colored LED light emitting structure and the first insulation layer, in which the conductive via electrically connects at least one of the first semiconductor layer, the second semiconductor layer, the third semiconductor layer and the fourth semiconductor layer; then in step S4, forming a first active device layer on the first insulation layer, in which the first active device layer includes at least one transistor; and finally in step S5, forming at least one electrode upon the first active device layer.

In some embodiments, the manufacturing method of the display element is not limited to the steps S1 to S5 mentioned above. For example, each of the steps S1 to S5 can includes other detailed steps. In some embodiments, other steps can be further included between two steps of the steps S1 to S5, before step S1, or after step S5. In the following description, at least the above mentioned steps will be described in detail.

Refer to FIG. 3, a buffer layer 180 can be formed on the substrate 110. Thereafter, forming a three-colored LED light emitting structure 120b on the buffer layer 180 of the substrate 110, in which the three-colored LED light emitting structure 120b includes a first semiconductor layer 121, a first multi-quantum well layer 122, a second semiconductor layer 123, a second multi-quantum well layer 124, a third semiconductor layer 125, a third multi-quantum well layer 126 and a fourth semiconductor layer 127 stacked in order. In some embodiments, a second insulation layer 128 can be formed on the third semiconductor layer 125, and a fifth semiconductor layer 129 can be formed on the second insulation layer 128. Besides, a third insulation layer 130 can be formed on the second semiconductor layer 123, and a sixth semiconductor layer 131 can be formed on the third insulation layer 130. Thereafter, forming a first insulation layer 140 on the three-colored LED light emitting structure 120b.

After the three-colored LED light emitting structure 120b is formed, conductive vias 160 can be formed in the three-colored LED light emitting structure 120b and the first insulation layer 140, in which the conductive vias 160 electrically connects one of the first semiconductor layer 121, the second semiconductor layer 123, the third semiconductor layer 125, the fourth semiconductor layer 127, the fifth semiconductor layer 129 and the sixth semiconductor layer 131. The step includes coating a photoresist on the first insulation layer 140; patterning the photoresist to form at least one opening; etching the three-colored LED light emitting structure 120b and the first insulation layer 140 in the opening to form at least one via hole; filling an insulation liner layer in the via hole; and plating a conductive material on the insulation liner layer to form the conductive via 160 or filling the via hole to form a conductive pillar.

Thereafter, forming a first active device layer 150 on the first insulation layer 140, in which the first active device layer 150 includes transistors 152 (see FIG. 4 and FIG. 5); The process of forming the transistors 152 includes depositing a semiconductor layer on the first insulation layer 140, wherein the semiconductor layer has a same material as the first semiconductor layer 121 or the second semiconductor layer 123; patterning the semiconductor layer to form at least one semiconductor active layer 152b; and forming at least one source 152c and at least one drain 152d on two opposite sides of the semiconductor active layer 152b. Forming the semiconductor active layer 152b and the three-colored LED light emitting structure 120b is formed by Metal-Organic Chemical Vapor Deposition (MOCVD), but the disclosure is not limited to this. Thereafter, forming at least one electrode 170 upon the first active device layer 150. The process can be done using deposition method to deposit a conductive metal upon the first active device layer 150, and then pattern the conductive metal layer to form the electrodes 170.

Since each layer of the three-colored LED light emitting structure is stacked in order on the same substrate in the manufacturing process, and the conductive via and the active device layer that includes control circuit are form on the three-colored LED light emitting structure afterwards, problems such as the effect on the yield and the process time caused by the transferring accuracy in the transferring and bonding process, the bonding strength between two components and the reliability are avoided as a result. Furthermore, the control circuit is located directly on the three-colored LED light emitting structure, which effectively reduces the area of a single element and improves the resolution and the effective light-emitting area.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A display element, comprising:
a substrate;
a three-colored LED light emitting structure located on the substrate and comprising:
a first semiconductor layer located on the substrate;
a first multi-quantum well layer located on the first semiconductor layer;
a second semiconductor layer located on the first multi-quantum well layer;
a second multi-quantum well layer located on the second semiconductor layer;
a third semiconductor layer located on the second multi-quantum well layer;
a third multi-quantum well layer located on the third semiconductor layer; and
a fourth semiconductor layer located on the third multi-quantum well layer;
a first insulation layer located on the fourth semiconductor layer;
a first active device layer located on the first insulation layer and comprising at least one transistor;
at least one conductive via or conductive pillar extending from the first active device layer to and electrically connected to at least one of the first semiconductor layer, the second semiconductor layer, the third semiconductor layer and the fourth semiconductor layer; and
at least one electrode located on the first active device layer.

2. The display element of claim 1, wherein the transistor comprises:
a semiconductor active layer;
a gate electrode electrically connected to one of the electrodes and achieving a purpose of current control through an electric field induction to a carrier in the semiconductor active layer across an insulation material;
a source or drain electrically connected to one of the electrodes; and
a drain or source electrically connected to the three-colored LED light emitting structure through the conductive via.

3. The display element of claim 2, wherein the semiconductor active layer comprises a same material as the first semiconductor layer, the second semiconductor layer, the third semiconductor layer or the fourth semiconductor layer.

4. The display element of claim 2, further comprising:
a second insulation layer located between the third semiconductor layer and the third multi-quantum well layer; and
a fifth semiconductor layer located between the second insulation layer and the third multi-quantum well layer.

5. The display element of claim 4, further comprising:
a third insulation layer located between the second semiconductor layer and the second multi-quantum well layer; and
a sixth semiconductor layer located between the third insulation layer and the second multi-quantum well layer.

6. The display element of claim 5, wherein an amount of the transistor is three, an amount of the conductive via is six, and the six conductive vias electrically connects to the first semiconductor layer, the second semiconductor layer, the third semiconductor layer, the fourth semiconductor layer, the fifth semiconductor layer and the sixth semiconductor layer respectively.

7. The display element of claim 6, wherein the first active device layer comprises an insulation material configured to electrically isolate the transistors.

8. The display element of claim 2, further comprising:
a second active device layer located on the first active device layer and electrically connected to the first active device layer.

9. The display element of claim 8, wherein the second active device layer comprises:
at least one capacitor electrically connected to one of the electrodes.

10. The display element of claim 9, wherein an amount of the transistor is six, an amount of the conductive via is six, an amount of the capacitor is three, three of the six transistors electrically connects to the three-colored LED light emitting structure.

11. The display element of claim 10, wherein the gate electrode of three of the six transistors electrically connects to the three capacitors and the source or the drain of the other three of the six transistors.

12. A manufacturing method of a display element, comprising:
forming a three-colored LED light emitting structure on a substrate, wherein the three-colored LED light emitting structure comprises a first semiconductor layer, a first multi-quantum well layer, a second semiconductor layer, a second multi-quantum well layer, a third semiconductor layer, a third multi-quantum well layer and a fourth semiconductor layer stacked in order;
forming a first insulation layer on the three-colored LED light emitting structure;
forming at least one conductive via in the three-colored LED light emitting structure and the first insulation layer, wherein the conductive via electrically connects at least one of the first semiconductor layer, the second semiconductor layer, the third semiconductor layer and the fourth semiconductor layer;
forming a first active device layer on the first insulation layer, wherein the first active device layer comprises at least one transistor; and
forming at least one electrode upon the first active device layer.

13. The manufacturing method of the display element of claim 12, wherein forming the conductive via in the three-colored LED light emitting structure and the first insulation layer comprises:
coating a photoresist on the first insulation layer;
patterning the photoresist to form at least one opening;
etching the three-colored LED light emitting structure and the first insulation layer in the opening to form at least one via hole;
filling an insulation liner layer in the via hole; and
plating a conductive material on the insulation liner layer to form the conductive via or filling the via hole to form a conductive pillar.

14. The manufacturing method of the display element of claim 12, further comprising:
forming a second insulation layer on the third semiconductor layer; and
forming a fifth semiconductor layer on the second insulation layer.

15. The manufacturing method of the display element of claim 14, further comprising:
forming a third insulation layer on the second semiconductor layer; and
forming a sixth semiconductor layer on the third insulation layer.

16. The manufacturing method of the display element of claim 12, further comprising:
depositing a semiconductor layer on the first insulation layer, wherein the semiconductor layer has a same material as the first semiconductor layer or the second semiconductor layer;
patterning the semiconductor layer to form at least one semiconductor active layer; and
forming at least one source and at least one drain on two opposite sides of the semiconductor active layer.

17. The manufacturing method of the display element of claim 16, wherein forming the semiconductor active layer and the three-colored LED light emitting structure is formed by Metal-Organic Chemical Vapor Deposition (MOCVD).
